(19) United States
(12) Patent Application Publication
(10) Pub. No.: US 2025/0056831 A1
(43) Pub. Date: Feb. 13, 2025

(54) ASYMMETRIC JUNCTIONLESS FIN FIELD EFFECT TRANSISTORS

(71) Applicant: GlobalFoundries Singapore Pte. Ltd., Singapore (SG)

(72) Inventors: Shyue Seng TAN, Singapore (SG); Vasanthan THIRUNAVUKKARASU, TAMIL NADU (IN); Eng Huat TOH, Singapore (SG); Kiok Boone Elgin QUEK, Singapore (SG)

(21) Appl. No.: 18/230,977

(22) Filed: Aug. 7, 2023

(51) Int. Cl. H01L 29/78; H01L 29/06; H01L 29/10; H01L 29/66

(52) U.S. Cl. CPC H01L 29/7853; H01L 29/0673; H01L 29/1033; H01L 29/66795

(57) ABSTRACT

The present disclosure relates to semiconductor structures and, more particularly, to asymmetric junctionless fin field effect transistor (FINFET) structures and methods of manufacture. The structure includes: a nanowire fin comprising a first width adjacent to a source region and a second width adjacent to a drain region, the first width and the second width being different dimensions; and a gate structure over the nanowire fin, the gate structure spanning over the first width and the second width and being between the source region and the drain region.

### BACKGROUND

The present disclosure relates to semiconductor structures and, more particularly, to asymmetric junctionless fin field effect transistor (FINFET) structures and methods of manufacture.

Junctionless (JL) FINFETs are devices that do not have a junction, where the gate acts as a gated resistor. The JL FINFET structures work on the principle of inversion of charge when no voltage is applied and charge accumulation when the device is in the saturation region. In JL FINFET structures, heavily n-type doped regions allow for high current flow when the JL FINFET is in the on-state. Due to the of the small cross-section of the nanowire fin in the JL FINFET, near full depletion of electrons across the width of the nanowire fin is expected; however, low leakage currents result in lower gate control performance.

### SUMMARY

In an aspect of the disclosure, a structure comprises: a nanowire fin comprising a first width adjacent to a source region and a second width adjacent to a drain region, the first width and the second width being different dimensions; and a gate structure over the nanowire fin, the gate structure spanning over the first width and the second width and being between the source region and the drain region.

In an aspect of the disclosure, a structure comprises: a nanowire fin comprising a first region and a second region which is different than the first region; and a gate structure over the nanowire fin and which spans over both the first region and the second region.

In an aspect of the disclosure, a method comprises: forming a nanowire fin comprising a first width adjacent to a source region and a second width adjacent to a drain region, the first width and the second width being different dimensions; and forming a gate structure over the nanowire fin, the gate structure spanning over the first width and the second width and being between the source region and the drain region.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a top cross-sectional view of an asymmetric junctionless (JL) fin field effect transistor (FINFET) and respective fabrication processes in accordance with aspects of the present disclosure.

FIG. 2 shows a top cross-sectional view of an asymmetric JL FINFET in accordance with additional aspects of the present disclosure.

FIG. 3 shows a top cross-sectional view of an asymmetric JL FINFET in accordance with further aspects of the present disclosure.

FIG. 4 shows a top cross-sectional view of an asymmetric JL FINFET in accordance with further aspects of the present disclosure.

FIGS. 5A-5D show respective fabrication processes of an asymmetric JL FINFET in accordance with aspects of the present disclosure.

FIGS. 6A-6D show respective fabrication processes of an asymmetric JL FINFET in accordance with additional aspects of the present disclosure.

### DETAILED DESCRIPTION

The present disclosure relates to semiconductor structures and, more particularly, to asymmetric junctionless fin field effect transistors (JL FINFETs) and methods of manufacture. More specifically, the present disclosure comprises a gate structure covering an asymmetric nanowire fin. For example, in embodiments, a width of the nanowire fin near the source region may be narrower than the width of the nanowire fin near the drain region of the JL FINFET. Advantageously, the structures described herein exhibit improved Ion and Ioff performance, e.g., reduce leakage currents. Moreover, in embodiments, the structures exhibit improved Gm which is linearly proportional to a wider drain critical dimension (compared to the critical dimension of the source). Higher Gm may be very useful for self-gain (Gm*Rout) of analog devices.

In more specific embodiments, the JL FINFET includes independently tunable nanowire fins between source and drain regions of the JL FINFET. For example, in embodiments, the width of the nanowire fin near the source region can be tuned to be narrower than the width of the nanowire fin near the drain region. For example, the nanowire fin, which is covered by a gate structure, may include a T-shape fin structure, stepped fin structure, trapezoidal fin structure with a sloped surface, or other shapes with a sloped surface, each of which have a narrower width near the source region compared to the drain region, e.g., critical dimension (CD) on the drain side is greater than the CD on the source side. By providing a narrower width of the nanowire fin at the source region, it is now possible to tune the device for improved drivability, performance and reliability. For example, a narrower source-side nanowire fin controls current leakage (I_{off}) while drain-side nanowire fin controls on-state resistance (Iₒₙ).

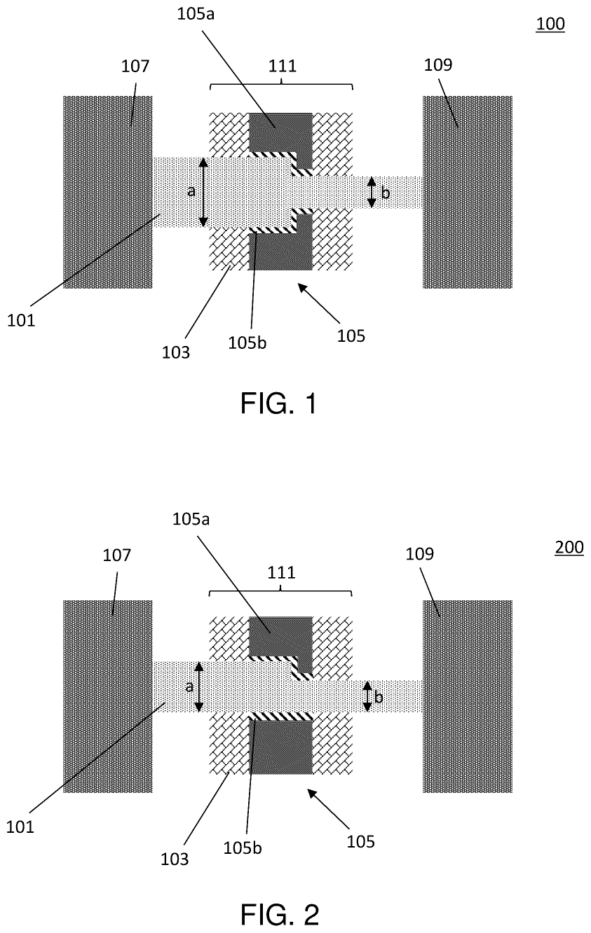

In embodiments, the FINFET can utilize double-gate and gate all around structures. In further exemplary embodiments, the FINFET may be a tri-gate JL FINFET with multiple gate dielectric materials covering the nanowire fin. In further exemplary embodiments, the asymmetric FINFET may be used in a non-junctionless FINFET, with the asymmetric fins comprising a narrower width near the drain region compared to the source region. For example, in FIGS. 1-4 below, the source region 107 and drain region 109 would be reversed with the narrower width of the nanowire fin being on the drain region and not the source region.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

FIG. 1 shows a top cross-sectional view of an asymmetric JL FINFET in accordance with aspects of the present disclosure. The asymmetric JL FINFET 100 of FIG. 1 includes a nanowire fin 101 formed from semiconductor substrate material. In embodiments, the nanowire fin 101 may be composed of any suitable semiconductor material including, but not limited to, Si, SiGe, SiGeC, SiC, GaAs, InAs, InP, and other III/V or II/VI compound semiconductors. The nanowire fin 101 may also comprise any suitable single crystallographic orientation (e.g., a (100), (110), (111), or (001) crystallographic orientation).

The semiconductor substrate may be a single semiconducting material such as bulk substrate comprising the semiconductor materials described herein. Alternatively, the semiconductor substrate may comprise semiconductor on insulator technology. The semiconductor on insulator technology may include, from bottom to top, a handle wafer, an insulator layer and the semiconductor substrate on top of the insulator layer. The insulator layer may comprise any suitable material, including silicon oxide, sapphire, other suitable insulating materials, and/or combinations thereof. An exemplary insulator layer may be a buried oxide layer (BOX). The insulator layer is formed by any suitable process, such as separation by implantation of oxygen (SIMOX), oxidation, deposition, and/or other suitable processes. The handle wafer may comprise any suitable semiconductor material as already described herein, and may be used as a support for the insulator layer and the semiconductor substrate.

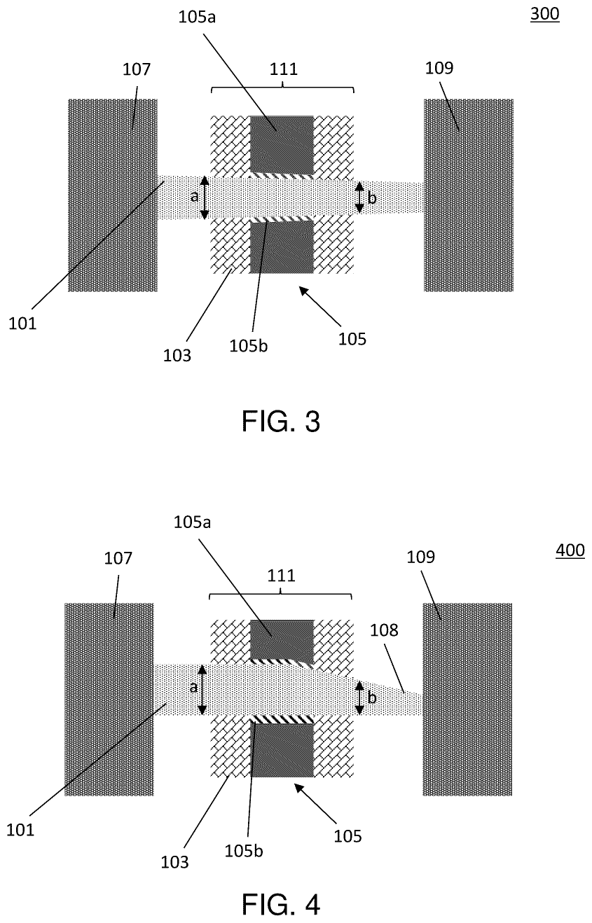

Still referring to FIG. 1, a portion of the nanowire fin 101 near the drain region 107 of the device includes a critical dimension of width ‘a’ and a portion of the nanowire 101 near the source region 109 of the device includes a critical dimension of width ‘b’. The width ‘b’ is narrower than the width ‘a.’ In exemplary embodiments, the width ‘a’ of the nanowire fin 101 may be about 20 nm, and preferably less than 15 nm. Also, in embodiments, viewing from the top, the cross-section of the nanowire fin 101 may be a T-shape (e.g., comprising a stepped feature); although other configurations are also contemplated herein as shown in FIGS. 2-4 as examples.

A gate structure 105 may be provided over the nanowire fin 101. In embodiments, the gate structure 105 includes gate electrode 105a and gate dielectric material(s) 105b, which cover a portion of the nanowire fin 100, over both the critical dimension of width ‘a’ and the critical dimension of width ‘b’. As should be understood by those of skill in the art, the portion of the nanowire fin 100 covered by the gate structure 105 will act as a channel region, with a depletion region 111 being on the thinner portion, e.g., width ‘b’, of the nanowire fin 101.

As should also be understood by those of ordinary skill in the art, the narrow section (e.g., width ‘b’) near the source region 109 will control the Vt (Ioff) of the device. For example, the asymmetric JL FINFET device 100 will turn off when the depletion region 111 is fully depleted, e.g., by preventing current to flow through the nanowire fin 101; whereas the drain region 107 of the device will control the on-state resistance. In other words, when the gate voltage (VG) is less than a threshold (Vth), the depletion region 111 is fully depleted of electrons; when the VG is about the same as the Vth a string-shaped channel of neutral n-type silicon connects the source and drain regions; and when the VG is greater than the Vth, but less than a flat-band voltage (VFB) the channel of neutral n-type semiconductor material expands in width and thickness.

In embodiments, the gate electrode 105a may be polysilicon material and the gate dielectric material(s) 105b may be a low-k or high-k dielectric material as is known in the art such that no further explanation is required herein for a complete understanding of the present disclosure. The polysilicon material may be doped with a p-type dopant or n-type dopant, depending on the device type. For example, in embodiments, the gate structure 105 may be heavily doped with a p-type dopant (e.g., boron), with the source region 109, drain region 107 and nanowire fin 111 being heavily doped with an n-type dopant (e.g., antimony, phosphorus or arsenic).

In embodiments, the gate structure 105 and nanowire fin 111 may be formed by introducing a concentration of a different dopant of opposite conductivity type using ion implantation processes. The source region 109 and drain region 107 may also be formed by an in-situ doping process as further described herein or, alternatively, by ion implantation processes. In embodiments, respective patterned implantation masks may be used to define selected areas exposed for the implantations. The implantation mask used to select the exposed area for forming the nanowire fin 111 is stripped after implantation, and before the implantation mask used to form gate structure 105, or vice versa. The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions. The p-type dopants may be, e.g., Boron (B), and the n-type dopants may be, e.g., Arsenic (As), Phosphorus (P) and Antimony (Sb), among other suitable examples.

Sidewall spacers 103 may surround the gate structure 105. The sidewall spacers 103 may be SiN or other low-k dielectric materials such as SiOCN, SiBCN, etc. In embodiments, the material for the sidewall spacers 103 may be deposited by a conventional deposition process, e.g., chemical vapor deposition (CVD), followed by an anisotropic etching process as is known in the art such that no further explanation is required for a complete understanding of the present disclosure.

In embodiments, the drain region 107 and source region 109 may comprise semiconductor material, selectively grown from the nanowire fin 101 to form raised source and drain regions. In embodiments, the semiconductor material may be SiGe or SiP, as examples. The drain region 107 and source region 109 may be in-situ doped with an appropriate dopant for an NFET device or PFET device as is understood by those of skill in the art such that no further explanation is required for a complete understanding of the present disclosure. Alternatively, the drain region 107 and source region 109 may be subjected to an ion implantation process as is known in the art.

FIG. 2 shows a top cross-sectional view of an asymmetric JL FINFET in accordance with additional aspects of the present disclosure. In FIG. 2, the asymmetric JL FINFET 200 shows a different configuration of the nanowire fin 101 covered by the gate structure 105. Illustratively, in the structure 200, the nanowire fin 101 may include a single stepped feature, e.g., L-shape. In this way the nanowire fin 101 near the source region 109 includes a critical dimension of the width ‘b’ that is narrower than the critical dimension of the width ‘a’ near the drain region 107. The remaining features are similar to the structure shown in FIG. 1.

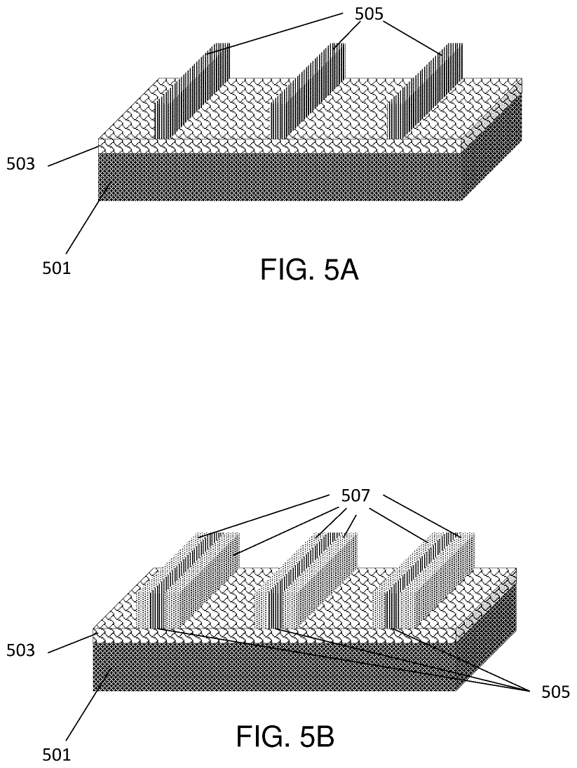

FIG. 3 shows a top cross-sectional view of an asymmetric JL FINFET in accordance with additional aspects of the present disclosure. In FIG. 3, the asymmetric JL FINFET 300 shows a different configuration of the nanowire fin 101 covered by the gate structure 105. Illustratively, in the structure 300, the nanowire fin 101 may be comprise a trapezoidal shape with a sloped surface such that a critical dimension of the width ‘b’ remains narrower than the critical dimension of the width ‘a’ near the drain region 107. The remaining features are similar to the structure shown in FIG. 1.

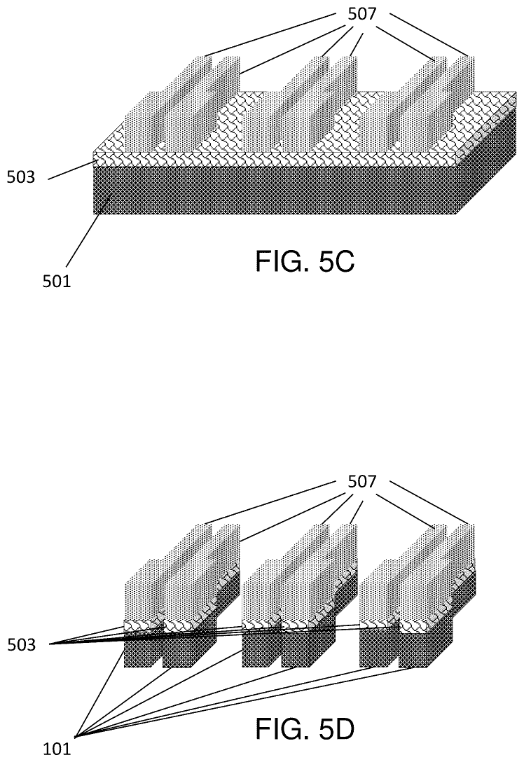

FIG. 4 shows a top cross-sectional view of an asymmetric JL FINFET in accordance with additional aspects of the present disclosure. In FIG. 4, the asymmetric JL FINFET 300 shows a different configuration of the nanowire fin 101 covered by the gate structure 105. Illustratively, in the structure 400, the nanowire fin 101 may be in a rectangular shape and trapezoidal shape (e.g., having a sloped edge 108). In this way the nanowire fin 101 near the source region 109 continues to include a width ‘b’ that is narrower than width ‘a’ of the nanowire fin 101 near the drain region 107. The remaining features are similar to the structure shown in FIG. 1.

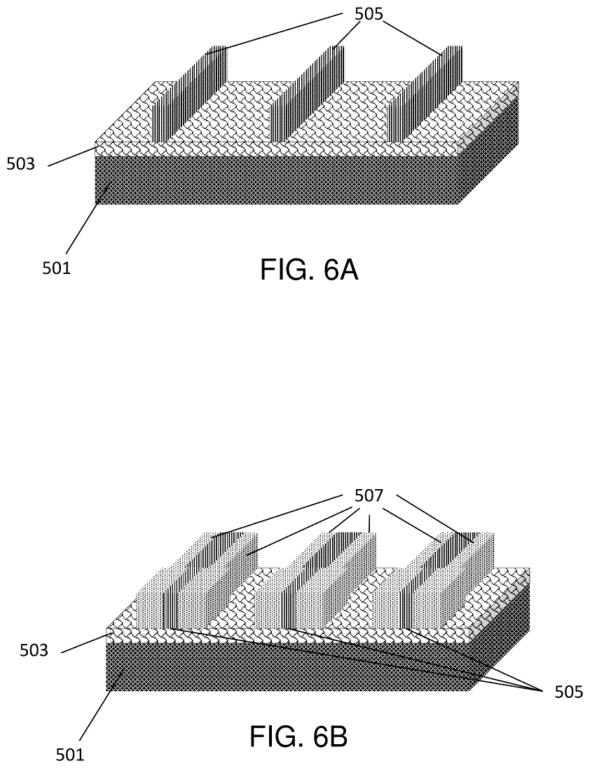

FIGS. 5A-5D show respective fabrication processes of an asymmetric JL FINFET in accordance with aspects of the present disclosure. In exemplary embodiments, the fabrication process may utilize a self-aligned double patterning (SADP) technique, with additional mask(s) to adjust and trim spacers 507 resulting in a narrower source side nanowire fin 101 with a width ‘b’ as shown in any of FIGS. 1-4. These same processes may be used to form the narrower side on the drain region.

For example, in FIG. 5A, a beginning structure includes a mandrel 505 on a top surface of hardmask 503. The hardmask 503 may be on a semiconductor substrate 501. The mandrel 505 may be SiN, for example, formed on semiconductor substrate 501. The mandrel may be patterned using conventional deposition, lithography and etching (RIE) processes.

In FIG. 5B, spacer material (e.g., material that is selective to the hardmask) may be deposited and patterned to form spacers 507 with a constant width along the length. The spacer material may be, for example, SiO₂ or other insulator material that is selectively etchable with respect to the mandrel material. The spacer material may be deposited by a CVD process, followed by an etching process.

In FIG. 5C, the mandrel is removed by a selective etching process. e.g., reactive ion etching (RIE) with an etch chemistry selective to the mandrel and which does not attack the spacers 507. The spacers 507 may be e.g., trimmed, to form spacers 507 with a smaller critical dimension on the source side. As shown in FIG. 5C, for example, the spacers 507 may be in stepped configuration, e.g., L-shape. Accordingly, the trimming process, e.g., trim etch, may be used to pattern the spacer material such that the width of the spacer 507 will have a different cross section at the source side and the drain side of the device.

In FIG. 5D, the pattern of the spacers 507 may transferred to the semiconductor substrate 507 to form the fin structure 101. The spacers 507 and hardmask 503 may be removed, leaving the fin structures 101 with a critical dimension (e.g., width) at the source side smaller than the critical dimension at the drain side.

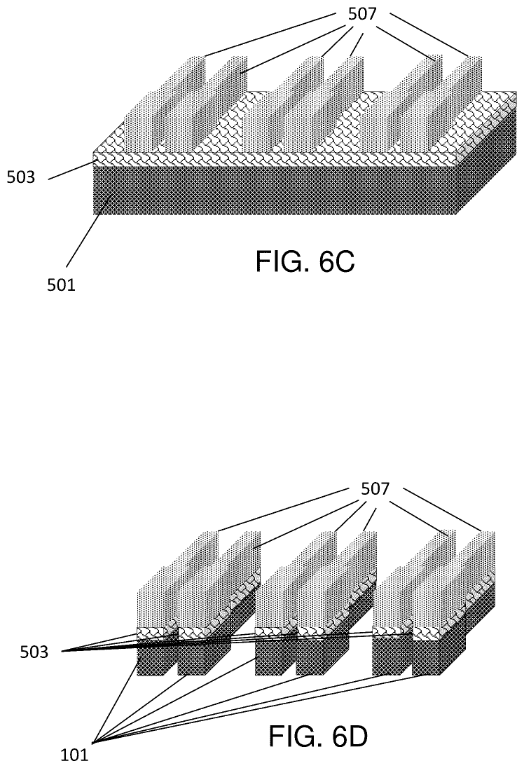

FIGS. 6A-6D show fabrication processes of an asymmetric JL FINFET in accordance with additional aspects of the present disclosure. For example, in FIG. 6A, a mandrel 505 is formed on a top surface of hardmask 503. The hardmask may be on the semiconductor substrate 501. The mandrel 505 may be SiN, for example, formed on the semiconductor substrate 501.

In FIG. 6B, spacer material (e.g., material that is selective to the hardmask) may be deposited and patterned to form spacers 507. In this process, a first spacer material is deposited for both source side and the drain side. The first spacer material can be removed on the source side, followed by a deposition and patterning of a second spacer material on both the drain side and the source side. Specifically, after removal of the spacer material on the source side, a second deposition process of spacer material will be provided to form the spacer on the source side and a wider spacer on the drain side, e.g., effectively adding additional spacer material on the drain side. The spacer material can then be pattered with a second masking process such that the critical dimension on the source side is smaller than the critical dimension on the drain side (which includes the combination of the first spacer deposition and the second spacer deposition). In this way, the critical dimension of spacer 1 on the source side is less than the critical dimension of spacer 1+ critical dimension of spacer 2 on the drain side.

In FIG. 6C, the mandrel is removed by a selective etching process. e.g., reactive ion etching (RIE) with an etch chemistry selective to the mandrel and which does not attack the spacers 507. In FIG. 6D, the pattern of the spacers 507 may transferred to the semiconductor substrate to form the fin structure 101, with two different critical dimensions, e.g., the critical dimension of the width on the source side being less than the critical dimension of the width on the drain side.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a nanowire fin comprising a first width adjacent to a source region and a second width adjacent to a drain region, the first width and the second width being different dimensions; and
a gate structure over the nanowire fin, the gate structure spanning over the first width and the second width and being between the source region and the drain region.

2. The structure of claim 1, wherein the first width is smaller than the second width.

3. The structure of claim 1, wherein nanowire fin includes an L-shape.

4. The structure of claim 1, wherein the nanowire fin includes a T-shape.

5. The structure of claim 1, wherein the nanowire fin includes a trapezoidal shape.

6. The structure of claim 1, wherein nanowire fin includes a rectangular shape and a trapezoid shape with a sloped surface.

7. The structure of claim 1, wherein the gate structure comprises a junctionless (JL) fin field-effect transistor (FINFET) structure.

8. The structure of claim 1, wherein the second width is smaller than the first width.

9. The structure of claim 1, wherein the first width of the nanowire fin comprises a depletion region.

10. The structure of claim 1, wherein the nanowire fin comprises an n-type dopant and the gate structure comprises a p-type dopant.

11. The structure of claim 1, wherein the gate structure includes multiple gate dielectric materials over the nanowire fin.

12. A structure comprising:
a nanowire fin comprising a first region and a second region which is different than the first region; and
a gate structure over the nanowire fin and which spans over both the first region and the second region.

13. The structure of claim 12, wherein the first region of the nanowire fin has a width smaller than the second region.

14. The structure of claim 13, wherein the first region is adjacent to a source region of the gate structure.

15. The structure of claim 12, wherein the nanowire fin includes a T-shape.

16. The structure of claim 12, wherein the nanowire fin includes a trapezoidal shape.

17. The structure of claim 12, wherein the nanowire fin includes stepped feature.

18. The structure of claim 12, wherein the nanowire fin comprises semiconductor material.

19. The structure of claim 12, wherein the gate structure comprises a junctionless field effect transistor.

20. A method comprising:
forming a gate structure covering a first region of a nanowire fin;
forming the nanowire fin additionally comprising a second and third region adjacent to the first region, wherein the nanowire fin is narrower in the second region than the third region.
